(19) United States
(12) Patent Application Publication
(10) Pub. No.: US 2009/0217974 A1
(43) Pub. Date: Sep. 3, 2009

(54) Organic active-layer solution for polymer solar cell and method for preparing the same

(75) Inventors: Fang-Chung Chen, Taipei (TW); Hsin-Chen Tseng, Taipei (TW); Chu-Jung Ko, Taipei (TW)

Correspondence Address: Juan Carlos A. Marquez;c/o Stites & Harbison PLLC, 1199 North Fairfax Street, Suite 900, Alexandria, VA, 22314-1437, US

(73) Assignee: National Chiao Tung University

(21) Appl. No.: 12/149,647

(22) Filed: May 6, 2008

(30) Foreign Application Priority Data
Feb. 29, 2008 (TW) 097107052

(51) Int. Cl. H01L 31/00

(52) U.S. Cl. 136/256

(57) ABSTRACT

An organic active-layer solution for a polymer solar cell and a method for preparing the same are provided, wherein the organic active-layer solution comprises an organic active-layer material, a first organic solvent and a second organic solvent. The first organic solvent has a boiling point ranging from 50° C. to 200° C. while the second organic solvent has a boiling point ranging from 150° C. to 300° C. The second organic solvent is added into the first organic solvent to dissolve the organic active-layer material. As the second organic solvent has a higher boiling point (a lower evaporation speed), it can directly lower an evaporation speed of the organic active-layer solution, thereby simplifying a manufacturing process of the polymer solar cell and increasing a power conversion efficiency of the polymer solar cell.

### BACKGROUND OF THE INVENTION

1. Technical Field

The present invention relates to an organic active-layer solution for a polymer solar cell and a method for preparing the same. More particularly, the present invention relates to an organic active-layer solution and a method for preparing the organic active-layer solution wherein the organic active-layer can be used to simplify a manufacturing process of a polymer solar cell and increase a power conversion efficiency of the polymer solar cell.

2. Description of Related Art

FIG. 1 is a schematic structural drawing of a polymer solar cell 10. As shown in FIG. 1, the polymer solar cell 10 comprises a substrate 11, a conductive layer 12, a conductive polymer layer 13, an organic active layer 14 and an electrode 15. The polymer solar cell 10 absorbs photons that excite electrons and holes in the organic active layer 14, so that electrons and holes are transported between the conductive layer 12 and the electrode 15 and thereby create a potential difference. Thus, electricity is generated from the polymer solar cell 10.

The substrate 11 can be a flexible substrate such as, for example, a plastic substrate while the conductive layer 12 can be made of, for example, indium tin oxide (ITO). A process for manufacturing the polymer solar cell 10 comprises the following steps. To begin with, the conductive layer 12 is grown on the substrate 11. Then, the conductive layer 12 is coated with the conductive polymer layer 13, on which the organic active layer 14 is further deposited. The organic active layer 14 is then treated with, among others, an annealing treatment before the electrode 15 is formed thereon by vapor deposition, wherein the electrode 15 can be a calcium electrode. In order to protect the calcium electrode, an aluminum electrode can be formed thereon by vapor deposition, which completes the manufacturing process of the polymer solar cell 10.

In the foregoing process, the organic active layer 14 receives the annealing treatment to increase a power conversion efficiency of the polymer solar cell 10, wherein the annealing treatment includes, for example, thermal annealing and solvent annealing. Solvent annealing begins by dissolving the organic active layer 14 in an organic solvent and then depositing the organic active layer 14 on the conductive polymer layer 13. By lowering an evaporation speed of the organic solvent, organic polymer molecules in the organic active layer 14 are rearranged during an evaporation process of the organic solvent, so that the organic polymer molecules in the organic active layer 14 are arranged in a more orderly manner. The organic active layer 14 can be made of, for example, a mixture of poly(3-hexylthiophene) (P3HT) and [6,6]-phenyl C61-butyric acid methyl ester (PCBM).

However, in order to lower the evaporation speed of the organic solvent, the polymer solar cell 10 has to stay in an environment having a high saturated vapor pressure or in a closed environment for dozens of hours, which is very time-consuming. In other words, solvent annealing has a low economic efficiency when used in mass production because not only an environment having a high saturated vapor pressure or a closed environment is required, but also it takes a lot of time to complete the annealing process.

### SUMMARY OF THE INVENTION

The present invention aims to provide an organic active-layer solution for a polymer solar cell and a method for preparing the same, wherein a first organic solvent is added with a second organic solvent to dissolve an organic active-layer material, in which the first organic solvent has a relatively lower boiling point (a higher volatility) and the second organic solvent has a relatively higher boiling point (a lower volatility). The second organic solvent having the higher boiling point is added to directly lower an evaporation speed of the organic active-layer solution during a solvent annealing process, without requiring an environment having a high saturated vapor pressure or a closed environment. Therefore, the time needed to complete the solvent annealing process can be reduced, and a manufacturing process of the polymer solar cell is simplified. At the same time, a power conversion efficiency of the polymer solar cell can also be increased.

To achieve this end, the present invention provides an organic active-layer solution for a polymer solar cell. The organic active-layer solution comprises an organic active-layer material, a first organic solvent having a boiling point ranging from 50° C. to 200° C., and a second organic solvent having a boiling point ranging from 150° C. to 300° C.

To achieve the aforementioned end, the present invention further provides a method for preparing an organic active-layer solution for a polymer solar cell. The method comprises steps of: providing an organic active-layer material; dissolving the organic active-layer material in a first organic solvent, wherein the first organic solvent has a boiling point ranging from 50° C. to 200° C.; and adding a second organic solvent into the first organic solvent, wherein the second organic solvent has a boiling point ranging from 150° C. to 300° C.

Implementation of the present invention at least provides the following advantageous effects:

1. The time required for solvent annealing is shortened, thereby simplifying the manufacturing process of the polymer solar cell; and

2. A simpler manufacturing process is provided, for which no special environmental condition is required, thereby lowering a production cost of the polymer solar cell.

### BRIEF DESCRIPTION OF THE DRAWINGS

Features and advantages of the present invention will be described below in detail so that a person skilled in the pertinent art can understand and carry out the technical content of the present invention and readily comprehend the objectives and advantages of the present invention by reference to the content disclosed herein, the appended claims and the accompanying drawings, wherein:

FIG. 1 is a schematic structural drawing of a polymer solar cell;

FIG. 2 is a flow chart of a method for preparing an organic active-layer solution for a polymer solar cell according to the present invention;

FIG. 3 is a structural formula of 1.2-dichlorobenzene;

FIG. 4 is a structural formula of 1-chloronaphthalene;

FIG. 5 is a plot showing voltage versus current density for polymer solar cells made from organic active-layer solutions added with different volume percentages of a second organic solvent;

FIG. 6 is a table of component characteristics for polymer solar cells made from organic active-layer solutions added with different volume percentages of the second organic solvent;

FIG. 7 illustrates ultraviolet absorption spectrums of organic active layers made by adding different volume percentages of the second organic solvent; and

FIG. 8 illustrates X-ray diffraction patterns of organic active layers made by adding different volume percentages of the second organic solvent.

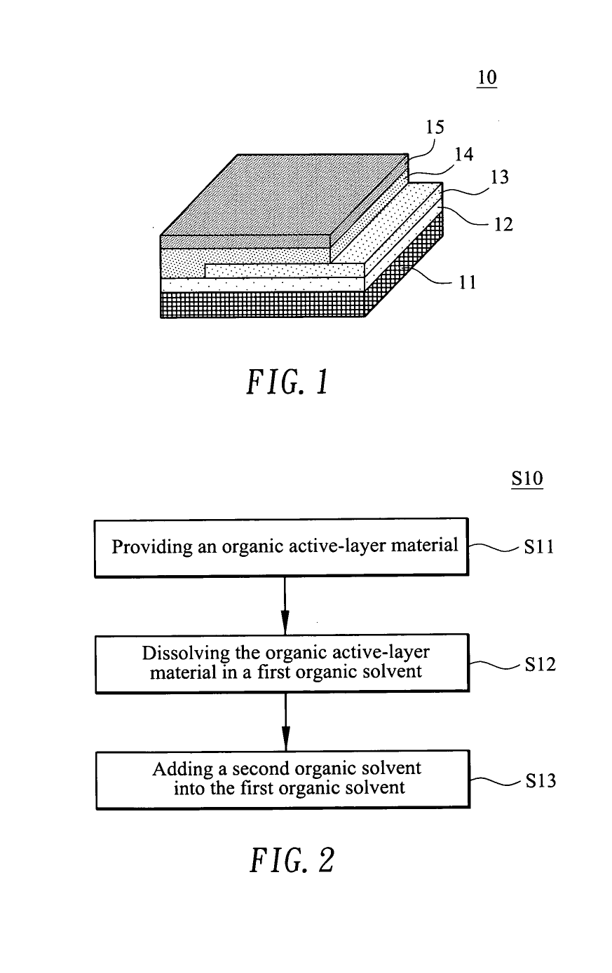

### DETAILED DESCRIPTION OF THE PREFERRED EMBODIMENT

### Organic Active-Layer Solution According to a First Embodiment of the Present Invention

An organic active-layer solution for a polymer solar cell according to a first embodiment of the present invention comprises an organic active-layer material, a first organic solvent and a second organic solvent.

The organic active-layer material is a combination of a p-type semiconductor material and an n-type semiconductor material. The organic active-layer material can react to light, so that holes in the p-type semiconductor material and electrons in the n-type semiconductor material are excited. The excited electrons and holes will be transported in the organic active-layer material and thereby generate an electric current.

For the polymer solar cell to have a higher power conversion efficiency, organic polymer molecules in the organic active-layer material must be arranged in a more orderly manner. When the organic polymer molecules are more orderly arranged and have a higher crystallinity, these molecules also have a greater effective conjugation length and a higher carrier mobility, so that the electrons and the holes can be transported at a higher speed. In other words, the less orderly and the more randomly the organic polymer molecules are arranged, the mobility of electrons and holes will be decreased, resulting in a higher series resistance of the organic active layer. On the contrary, the more orderly the organic polymer molecules are arranged, the mobility of electrons and holes will be increased, resulting in a lower series resistance of the organic active layer while increasing the power conversion efficiency of the polymer solar cell.

The p-type semiconductor material can be selected from the group consisting of polythiophene, polyfluorene, polyphenylenevinylene, derivatives of polythiophene, derivatives of polyfluorene, derivatives of polyphenylenevinylene, conjugated oligomers, and small molecules.

More particularly, the derivatives of polythiophene can be poly(3-hexylthiophene). The derivatives of polyfluorene can be poly(dioctylfluorene). The derivatives of polyphenylenevinylene can be poly[2-methoxy-5-(2-ethyl-hexyloxy)-1,4-phenylene vinylene]. The conjugated oligomers can be sexithiophene. The small molecules can be selected from the group consisting of pentacene, tetracene, hexabenzcoronene, phthalocyanine, porphyrines, derivatives of pentacene, derivatives of tetracene, derivatives of hexabenzcoronene, derivatives of phthalocyanine, and derivatives of porphyrines.

The n-type semiconductor material can be selected from the group consisting of C60; C60 derivatives; C70; C70 derivatives; carbon nanotubes; carbon-nanotube derivatives; 3,4,9,10-perylene tetracarboxylic-bis-benzimidazole (PTCBI); N,N′-dimethyl-3,4,9,10-Perylenetetracarboxylic acid diimide (Me-PTCDI); PTCBI derivatives; Me-PTCDI derivatives; polymers and semiconductor nanoparticles.

More particularly, the C60 derivatives can be phenyl C61-butyric acid methyl ester (PCBM). The polymers can be selected from the group consisting of poly(2,5,2′,5′-tetrahexyloxy-7,8′-dicyano-di-p-phenylenevinylene) (CN—PPV) and poly(9,9′-dioctylfluorene-co-benzothiadiazole) (F8BT). The carbon nanotubes can be selected from the group consisting of single-wall carbon nanotubes and multi-wall carbon nanotubes, wherein the carbon nanotubes have a cross-sectional diameter smaller than 100 nm. The semiconductor nanoparticles can be selected from the group consisting of titanium dioxide (TiO₂), cadmium selenide (CdSe) and cadmium sulfide (CdS).

The first organic solvent has a boiling point ranging from 50° C. to 200° C. and is used to dissolve the organic active-layer material. The first organic solvent can be, for example, 1.2-dichlorobenzene, chloroform, chlorobenzene, toluene, or xylenes.

The second organic solvent has a boiling point ranging from 150° C. to 300° C. and is added to the first organic solvent, wherein a volume percentage of the second organic solvent added to form the organic active-layer solution can range from 2% to 50%. For example, the organic active-layer material can be dissolved in the first organic solvent before the second organic solvent is added to the first organic solvent in which the organic active-layer material has dissolved. Alternatively, the second organic solvent can be added to the first organic solvent before the organic active-layer material is dissolved in the mixture. The second organic solvent can be, for example, 1-chloronaphthalene, 1-methylnaphthalene or 1,2,4-trichlorobenzene.

The second organic solvent has a relatively higher boiling point (a lower volatility) and therefore does not volatilize easily. In other words, the second organic solvent has a lower evaporation speed. Therefore, the second organic solvent can be used to directly lower an evaporation speed of the organic active-layer solution, so that the organic polymer molecules in the organic active-layer solution have sufficient time for rearrangement. As a result, the organic polymer molecules can be arranged in a more orderly manner while the power conversion efficiency of the polymer solar cell is enhanced. Furthermore, as it is no longer required to put the organic active-layer solution in an environment having a high saturated vapor pressure or a closed environment, the manufacturing process of the polymer solar cell can be simplified.

### Method for Preparing an Organic Active-Layer Solution According to a Second Embodiment of the Present Invention

As shown in FIG. 2, a method S10 for preparing an organic active-layer solution for a polymer solar cell according to a second embodiment of the invention comprises steps of: providing an organic active-layer material (S11); dissolving the organic active-layer material in a first organic solvent (S12); and adding a second organic solvent into the first organic solvent (S13).

Providing an organic active-layer material (S11): The organic active-layer material is a combination of a p-type semiconductor material and an n-type semiconductor material. The p-type semiconductor material and the n-type semiconductor material will not be explained further here as a description thereof has been given in the above explanation regarding the organic active-layer solution according to the first embodiment of the present invention.

Dissolving the organic active-layer material in a first organic solvent (S12): The organic active-layer material, being a solid-state material, can be dissolved by the first organic solvent. The first organic solvent has a boiling point ranging from 50° C. to 200° C., which is lower than a boiling point of the second organic solvent. In other words, compared with the second organic solvent, the first organic solvent has a higher evaporation speed. The first organic solvent can be, for example, 1.2-dichlorobenzene, chloroform, chlorobenzene, toluene, or xylenes.

Adding a second organic solvent into the first organic solvent (S13): The second organic solvent is added to the first organic solvent in which the organic active-layer material has dissolved, thereby forming an organic active-layer solution. Alternatively, the second organic solvent can be added to the first organic solvent before the organic active-layer material is dissolved in the mixture. The second organic solvent has a boiling point ranging from 150° C. to 300° C., which is higher than the boiling point of the first organic solvent. In other words, the second organic solvent has a lower evaporation speed.

Because the second organic solvent has a lower evaporation speed, the second organic solvent can be used to directly lower an evaporation speed of the organic active-layer solution, without having to put the organic active-layer solution in an environment having a high saturated vapor pressure or in a closed environment, so that the manufacturing process of the polymer solar cell can be simplified. Moreover, because the second organic solvent has a lower evaporation speed, the organic polymer molecules in the organic active-layer solution are allowed more time for rearranging themselves while the second organic solvents slowly volatilizes. As a result, the organic polymer molecules are allowed to rearrange in a more orderly manner and with a higher crystallinity, thereby increasing the power conversion efficiency of the polymer solar cell.

The second organic solvent can be, for example, 1-chloronaphthalene, 1-methylnaphthalene or 1,2,4-trichlorobenzene. The volume percentage of the second organic solvent added to the first organic solvent can be varied to increase or decrease an evaporation time of the organic active-layer solution and thereby influence component characteristics of the polymer solar cell. The volume percentage of the second organic solvent in the solution can range from 2% to 50%.

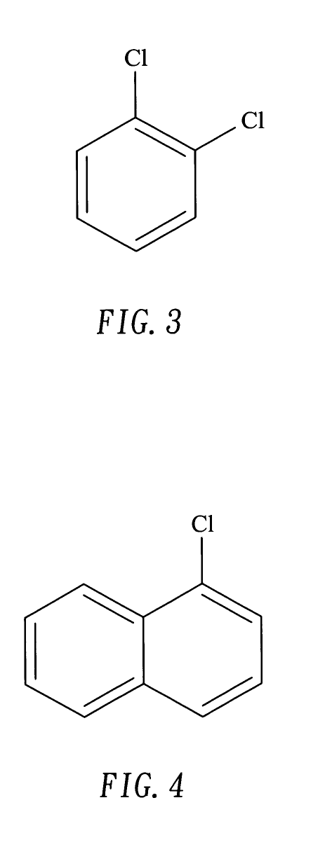

In order to facilitate understanding of the effects of this embodiment, organic active-layer solutions were prepared using P3HT/PCBM as the organic active-layer material, 1.2-dichlorobenzene as the first organic solvent, and 1-chloronaphthalene as the second organic solvent. Polymer solar cells were made from organic active-layer solutions added with different volume percentages of 1-chloronaphthalene for a comparison of component characteristics of the polymer solar cells, thereby illustrating the effects of this embodiment. FIG. 3 shows a structural formula of 1.2-dichlorobenzene, which has a boiling point approximately between 178° C. and 180° C. and a saturated vapor pressure of 1.2 mmHg at 20° C. FIG. 4 shows a structural formula of 1-chloronaphthalene, which has a boiling point of about 259° C. and a saturated vapor pressure of 0.038 mmHg at 20° C.

First of all, the component characteristics of the polymer solar cell are defined as follows. An open-circuit voltage (V_{OC}) is defined as a voltage when a load impedance of the polymer solar cell is infinity, i.e., when an external current has a value of zero. A short-circuit current density (J_{SC}) is defined as a current density when the voltage is zero. In addition, any working point along a characteristic curve of current density versus voltage of the polymer solar cell has an output power (P) equal to a product of a voltage (V) and a current density (J), i.e., P=V×J, corresponding to that working point, wherein a particular working point (Vₘ, Jₘ) has a maximum output power (Pₘ, Pₘ=Vₘ×Jₘ). A filling factor (FF) is therefore defined as a ratio between the maximum output power and a product of the open-circuit voltage and the short-circuit current density (FF=(Vₘ×Jₘ)/(V_{OC}×J_{SC})).

In order to have better component characteristics, a polymer solar cell must have, in addition to a high open-circuit voltage and a high short-circuit current density, an FF value as close to 1 as possible because the filling factor shows how close the maximum output power is to the product of the open-circuit voltage and the short-circuit current density. As the power conversion efficiency (η) of a polymer solar cell is defined as a ratio between an output energy and an input light energy (Pᵢₙ), i.e., η=(V_{OC}×J_{SC}×FF)/Pᵢₙ, the closer the FF value is to 1, the higher the power conversion efficiency is.

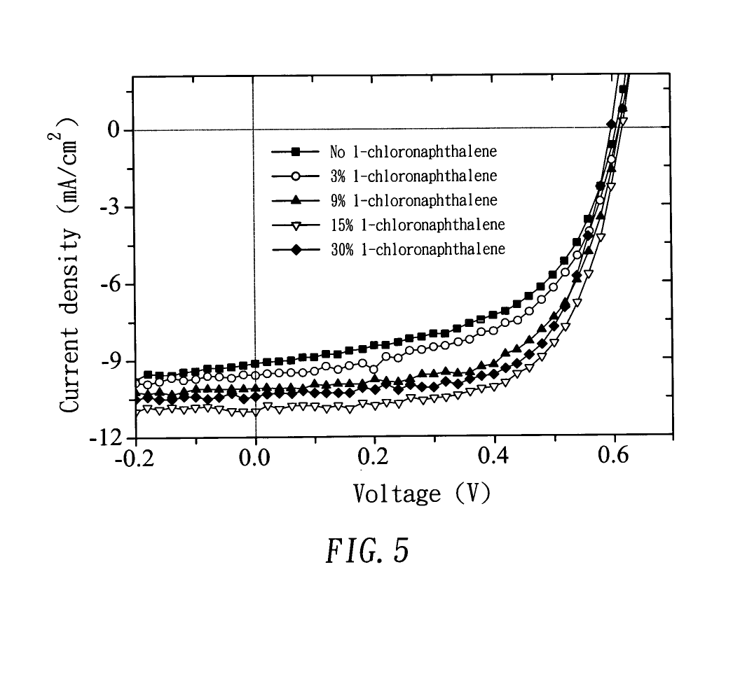

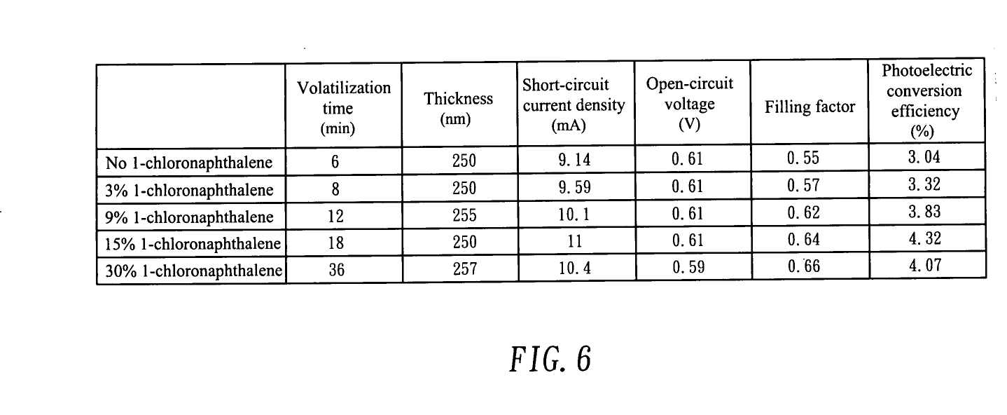

FIG. 5 illustrates short-circuit current densities versus voltages of polymer solar cells made from organic active-layer solutions added with 3%, 9%, 15% and 30% of 1-chloronaphthalene. FIG. 6 illustrates thicknesses and evaporation times of deposits of the organic active-layer solutions added with 3%, 9%, 15% and 30% of 1-chloronaphthalene on the conductive polymer layer 13, along with the various component characteristics of the polymer solar cells.

As shown in FIG. 5, when the volume percentage of 1-chloronaphthalene added to form the organic active-layer solutions is increased, the open-circuit voltages of the polymer solar cells are not decreased as the volume percentages of 1-chloronaphthalene are increased. More particularly, referring to FIG. 6, where the deposited thicknesses of all the organic active-layer solutions are approximately 250 nm, the open-circuit voltages of the polymer solar cells are all approximately 0.6 V. Moreover, referring to FIG. 5, as the volume percentages of 1-chloronaphthalene added to form the organic active-layer solutions are increased, the short-circuit currents density and the filling factors of the polymer solar cells are both increased. More particularly, as shown in FIG. 6, when the volume percentage of 1-chloronaphthalene added to form the organic active-layer solution is 15%, the polymer solar cell thus made has a maximum short-circuit current density of approximately 11 mA and a maximum power conversion efficiency of approximately 4.32%.

Referring to FIG. 6, when the volume percentage of 1-chloronaphthalene added to form the organic active-layer solution is 15%, the polymer solar cell thus made has the maximum power conversion efficiency while the evaporation time of the organic active-layer solution is reduced to approximately 18 min. Therefore, it can be known that implementation of the embodiment not only enhances the power conversion efficiency of the polymer solar cell, but also significantly shortens the evaporation time of the organic active-layer solution from dozens of hours to dozens of minutes.

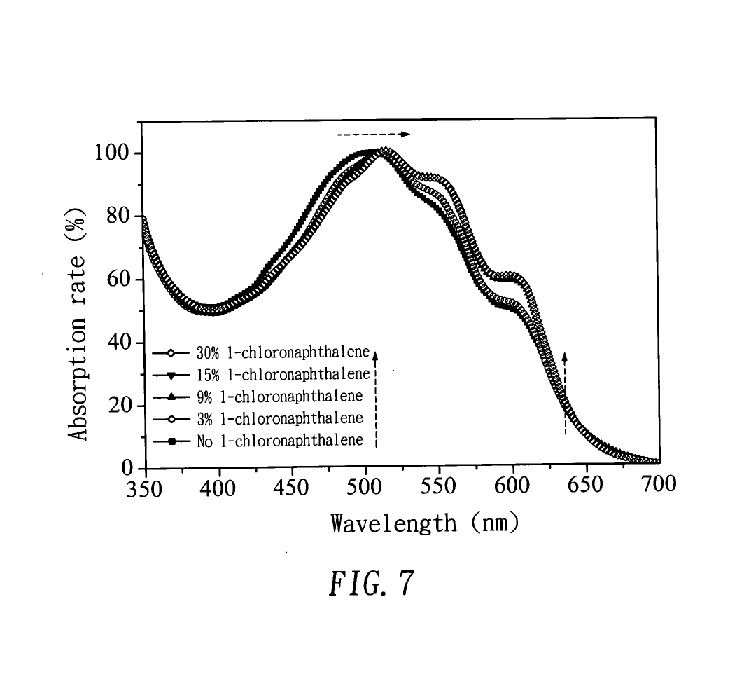

FIG. 7 illustrates ultraviolet absorption spectrums of organic active layers made by adding 3%, 9%, 15% and 30% of 1-chloronaphthalene, wherein the spectrums were obtained after the 1-chloronaphthalene had volatilized. As shown in FIG. 7, a curve shifted more towards the right signifies that more light is absorbed by the corresponding organic active layer. More particularly, the organic active layers made by adding 15% and 30% of 1-chloronaphthalene absorb more light than do the organic active layers made by adding 3% and 9% of 1-chloronaphthalene. Furthermore, a peak in the spectrum implies that the organic polymer molecules in the organic active layer are more orderly arranged, which leads to a lower series resistance of the organic active layer and further to a higher current in the organic active layer.

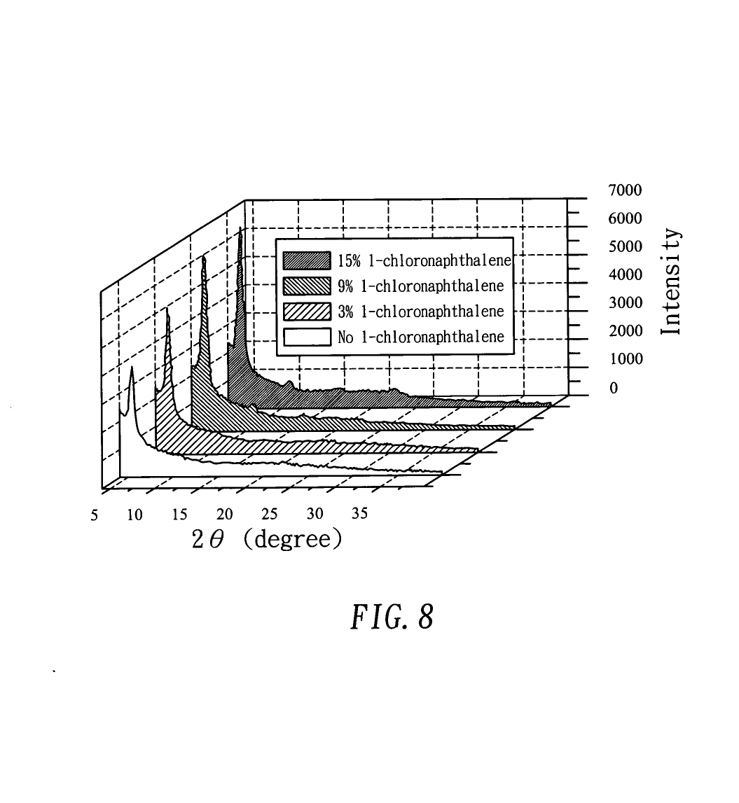

An X-ray diffraction meter manufactured by PANalytical of the Netherlands (model: X'Pert Pro) was used to analyze P3HT dissolved with 3%, 9%, 15% and 30% of 1-chloronaphthalene, respectively, after the 1-chloronaphthalene had volatilized. The X-ray diffraction patterns obtained are shown in FIG. 8. As shown in FIG. 8, when a value equal to two times the angle of incidence for X-ray diffraction (20) is 5.4°, the P3HT dissolved with 15% of 1-chloronaphthalene has the highest diffraction intensity, which means that the organic polymer molecules in that particular organic active layer are arranged in the most orderly manner.

In summary, addition of the second organic solvent directly lowers the volatility and evaporation speed of the organic active-layer solution, so that the organic polymer molecules in the organic active-layer solution are arranged in a more orderly manner. Therefore, when the method for preparing the organic active-layer solution according to this embodiment of the present invention is used in mass production, the power conversion efficiency of the polymer solar cell thus made can be increased while the manufacturing process of the polymer solar cell is simplified, wherein no additional special environments, such as an environment having a high saturated vapor pressure or a closed environment, are required.

The present invention has been described with preferred embodiments thereof, which are intended to demonstrate the features of the present invention so that a person skilled in the art can understand and carry out the content of the present invention. It is understood that the embodiments are not intended to limit the scope of the present invention. Therefore, all equivalent alterations or modifications which do not depart from the spirit of the present invention are encompassed by the appended claims.

What is claimed is:

1. An organic active-layer solution for a polymer solar cell, comprising:
an organic active-layer material;
a first organic solvent, having a boiling point ranging from 50° C. to 200° C.; and
a second organic solvent, having a boiling point ranging from 150° C. to 300° C.

2. The organic active-layer solution as claimed in claim 1, wherein the organic active-layer material is a combination of a p-type semiconductor material and an n-type semiconductor material, in which the p-type semiconductor material is selected from the group consisting of polythiophene, polyfluorene, polyphenylenevinylene, derivatives of polythiophene, derivatives of polyfluorene, derivatives of polyphenylenevinylene, conjugated oligomers, and small molecules; and the n-type semiconductor material is selected from the group consisting of C60; C60 derivatives; C70; C70 derivatives; carbon nanotubes; carbon-nanotube derivatives; 3,4,9,10-perylene tetracarboxylic-bis-benzimidazole (PTCBI); N, N′-dimethyl-3,4,9,10-Perylenetetracarboxylic acid diimide (Me-PTCDI); PTCBI derivatives; Me-PTCDI derivatives; polymers and semiconductor nanoparticles.

3. The organic active-layer solution as claimed in claim 2, wherein the derivatives of polythiophene are poly(3-hexylthiophene).

4. The organic active-layer solution as claimed in claim 2, wherein the C60 derivatives are phenyl C61-butyric acid methyl ester (PCBM).

5. The organic active-layer solution as claimed in claim 1, wherein the first organic solvent is 1.2-dichlorobenzene, chloroform, chlorobenzene, toluene or xylenes.

6. The organic active-layer solution as claimed in claim 1, wherein the second organic solvent is 1-chloronaphthalene, 1-methylnaphthalene or 1,2,4-trichlorobenzene.

7. The organic active-layer solution as claimed in claim 1, wherein the second organic solvent has a volume percentage ranging from 2% to 50%.

8. A method for preparing an organic active-layer solution for a polymer solar cell, comprising steps of:
providing an organic active-layer material;
dissolving the organic active-layer material in a first organic solvent, wherein the first organic solvent has a boiling point ranging from 50° C. to 200° C.; and
adding a second organic solvent into the first organic solvent, wherein the second organic solvent has a boiling point ranging from 150° C. to 300° C.

9. The method for preparing the organic active-layer solution as claimed in claim 8, wherein the organic active-layer material is a combination of a p-type semiconductor material and an n-type semiconductor material, in which the p-type semiconductor material is selected from the group consisting of polythiophene, polyfluorene, polyphenylenevinylene, derivatives of polythiophene, derivatives of polyfluorene, derivatives of polyphenylenevinylene, conjugated oligomers, and small molecules; and the n-type semiconductor material is selected from the group consisting of C60; C60 derivatives; C70; C70 derivatives; carbon nanotubes; carbon-nanotube derivatives; 3,4,9,10-perylene tetracarboxylic-bis-benzimidazole (PTCBI); N,N′-dimethyl-3,4,9,10-Perylenetetracarboxylic acid diimide (Me-PTCDI); PTCBI derivatives; Me-PTCDI derivatives; polymers and semiconductor nanoparticles.

10. The method for preparing the organic active-layer solution as claimed in claim 9, wherein the derivatives of polythiophene are poly(3-hexylthiophene).

11. The method for preparing the organic active-layer solution as claimed in claim 9, wherein the C60 derivatives are phenyl C61-butyric acid methyl ester (PCBM).

12. The method for preparing the organic active-layer solution as claimed in claim 8, wherein the first organic solvent is 1.2-dichlorobenzene, chloroform, chlorobenzene, toluene or xylenes.

13. The method for preparing the organic active-layer solution as claimed in claim 8, wherein the second organic solvent is 1-chloronaphthalene, 1-methylnaphthalene or 1,2,4-trichlorobenzene.

14. The method for preparing the organic active-layer solution as claimed in claim 8, wherein the second organic solvent has a volume percentage ranging from 2% to 50%.
